(19) United States
(12) Patent Application Publication
(10) Pub. No.: US 2025/0336842 A1
(43) Pub. Date: Oct. 30, 2025

(54) SEMICONDUCTOR PACKAGE INCLUDING A REDISTRIBUTION STRUCTURE AND A LASER MARK

(71) Applicant: SAMSUNG ELECTRONICS CO., LTD., SUWON-SI (KR)

(72) Inventor: Junghoon KANG, Suwon-si (KR)

(21) Appl. No.: 19/019,680

(22) Filed: Jan. 14, 2025

(30) Foreign Application Priority Data
Apr. 30, 2024 (KR) 10-2024-0058122

(51) Int. Cl. H01L 23/544; H01L 23/498

(52) U.S. Cl. CPC H01L 23/544; H01L 23/49816; H01L 2223/54433

(57) ABSTRACT

A semiconductor package includes: an encapsulation layer configured to seal at least one semiconductor chip; a redistribution structure arranged on the encapsulation layer, wherein the redistribution structure includes a redistribution metal layer and a redistribution insulating layer disposed on the redistribution metal layer, and the redistribution metal layer includes a redistribution pad formed at an upper portion thereof; a laser mark metal layer spaced apart from the redistribution pad and arranged on the redistribution insulating layer; a pad insulating layer configured to cover the redistribution structure and the laser mark metal layer, wherein the pad insulating layer includes a transparent insulating layer or a translucent insulating layer, and includes a laser mark exposure hole exposing the laser mark metal layer; and a laser mark arranged inside or on a surface of the laser mark metal layer that is exposed by the laser mark exposure hole.

### CROSS-REFERENCE TO RELATED APPLICATION

This application claims priority under 35 U.S.C. § 119 to Korean Patent Application No. 10-2024-0058122 filed on Apr. 30, 2024 in the Korean Intellectual Property office, the disclosure of which are incorporated by reference herein in its entirety.

### TECHNICAL FIELD

The present inventive concept relates to a semiconductor package, and more particularly, to a semiconductor package including a redistribution structure and a laser mark.

### DISCUSSION OF THE RELATED ART

Laser marks indicating product information may be displayed on surfaces of semiconductor packages that include semiconductor chips. As the semiconductor packages become thinner, it may become more difficult to form the laser marks on the semiconductor packages without damaging a redistribution structure that includes a redistribution layer and a redistribution insulating layer. In addition, it is desirable that there is good visibility of the laser marks so that users can easily recognize them.

### SUMMARY

According to an embodiment of the present inventive concept, a semiconductor package includes: an encapsulation layer configured to seal at least one semiconductor chip; a redistribution structure arranged on the encapsulation layer, wherein the redistribution structure includes a redistribution metal layer and a redistribution insulating layer disposed on the redistribution metal layer, and the redistribution metal layer includes a redistribution pad formed at an upper portion thereof; a laser mark metal layer spaced apart from the redistribution pad and arranged on the redistribution insulating layer; a pad insulating layer configured to cover the redistribution structure and the laser mark metal layer, wherein the pad insulating layer includes a transparent insulating layer or a translucent insulating layer, and includes a laser mark exposure hole exposing the laser mark metal layer; and a laser mark arranged inside or on a surface of the laser mark metal layer that is exposed by the laser mark exposure hole.

According to an embodiment of the present inventive concept, a semiconductor package includes: a package body having a fan-in region and a fan-out region at least partially surrounding the fan-in region, wherein a substrate wiring structure is arranged in the package body and in the fan-out region; a semiconductor chip arranged in the fan-in region; an encapsulation layer configured to seal the semiconductor chip and the package body; a redistribution structure arranged on the encapsulation layer and electrically connected to the substrate wiring structure, wherein the redistribution structure includes a redistribution metal layer and a redistribution insulating layer configured to insulate the redistribution metal layer, and the redistribution metal layer incudes a redistribution pad formed at an upper portion thereof; a laser mark metal layer spaced apart from the redistribution pad and arranged on the redistribution insulating layer; a pad insulating layer configured to cover the redistribution structure and the laser mark metal layer, wherein the pad insulating layer includes a transparent insulating layer or a translucent insulating layer, and the pad insulating layer includes a laser mark exposure hole exposing the laser mark metal layer; and a laser mark arranged inside or on a surface of the laser mark metal layer that is exposed by the laser mark exposure hole.

According to an embodiment of the present inventive concept, a semiconductor package includes: a lower package; and an upper package stacked on the lower package, wherein the lower package includes: a package body including a fan-in region and a fan-out region at least partially surrounding the fan-in region, wherein a substrate wiring structure is arranged in the package body and in the fan-out region; a lower semiconductor chip arranged in the fan-in region; an encapsulation layer configured to seal the semiconductor chip and the package body; an upper redistribution structure arranged on the encapsulation layer, wherein the upper redistribution structure includes an upper redistribution metal layer and an upper redistribution insulating layer disposed on the upper redistribution metal layer, and the upper redistribution metal layer includes an upper redistribution pad formed at an upper portion thereof; a laser mark metal layer spaced apart from the upper redistribution pad and arranged on the upper redistribution insulating layer; an upper pad insulating layer configured to cover the upper redistribution structure and the laser mark metal layer, wherein the upper pad insulating layer includes a transparent insulating layer or a translucent insulating layer, and includes a laser mark exposure hole exposing the laser mark metal layer; a laser mark arranged inside or on a surface of the laser mark metal layer that is exposed by the laser mark exposure hole; a lower redistribution structure arranged under lower surfaces of the package body and the semiconductor chip and including a lower redistribution metal layer formed in the fan-in region and the fan-out region; a lower redistribution pad arranged on the lower redistribution structure and electrically connected to the lower redistribution metal layer; a ball land layer arranged on the lower redistribution pad; a lower pad insulating layer disposed on the lower redistribution pad and the ball land layer; and a lower solder ball disposed on the ball land layer, wherein the upper package includes: an upper solder ball arranged on the upper redistribution pad; and an upper semiconductor chip mounted on the upper redistribution structure and electrically connected to the upper redistribution structure via the upper solder ball.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view of a semiconductor package according to an embodiment of the present inventive concept;

FIG. 2 is an enlarged view of region EN1 in FIG. 1;

FIG. 3 is a cross-sectional view of major components of a semiconductor package, according to an embodiment of the present inventive concept;

FIG. 4 is a cross-sectional view of major components of a semiconductor package, according to an embodiment of the present inventive concept;

FIG. 5 is a cross-sectional view of major components of a semiconductor package, according to an embodiment of the present inventive concept;

FIGS. 6, 7, 8, 9, 10, 11, 12, 13, 14, 15, 16, and 17 are cross-sectional views of components for describing a manufacturing method of the semiconductor packages of FIGS. 1 and 2, according to an embodiment of the present inventive concept;

FIG. 18 is a cross-sectional view of components of a semiconductor package, according to an embodiment of the present inventive concept;

FIG. 19 is a block diagram of a configuration of a semiconductor package, according to an embodiment of the present inventive concept; and

FIG. 20 is a schematic block diagram of a configuration of a semiconductor package, according to an embodiment of the present inventive concept.

### DETAILED DESCRIPTION OF THE EMBODIMENTS

Hereinafter, embodiments of the present inventive concept are described in detail with reference to the accompanying drawings. Identical or similar reference numerals or reference numbers are used for the same constituent elements in the drawings and specification, and duplicate descriptions thereof are briefly given or omitted. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

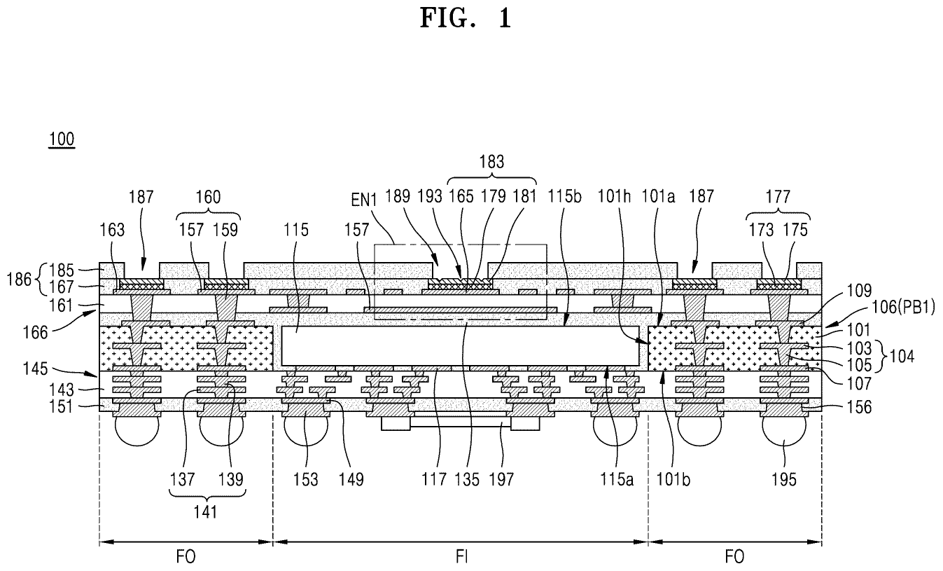

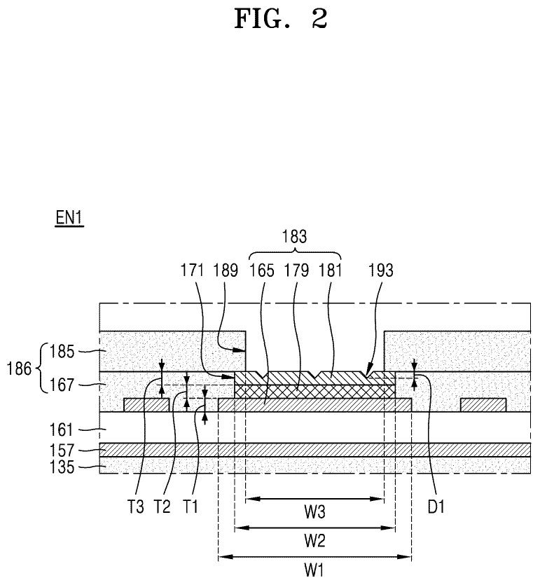

FIG. 1 is a cross-sectional view a semiconductor package 100, according to an embodiment of the present inventive concept, and FIG. 2 is an enlarged view of region EN1 in FIG. 1.

The semiconductor package 100 may include a fan-out semiconductor package according to an embodiment of the present inventive concept. The semiconductor package 100 may include a wiring substrate 106 having a fan-in region FI, which corresponds to a through hole 101h that is arranged in the fan-in region FI, and a fan-out region FO, which is located on both sides of the fan-in region FI. For example, the fan-out region FO may at least partially surround the fan-in region FI in a plan view.

The wiring substrate 106 may include a package body PB1. The package body PB1 may include a package element. The wiring substrate 106 may include an insulating substrate. The wiring substrate 106 may include a printed circuit board. For example, the wiring substrate 106 may be a frame substrate. The semiconductor package 100 may include a package of a fan-out panel level package (FOPLP) form. The wiring substrate 106 may include a body 101 located on sides of the through hole 101h, a substrate wiring structure 104 formed in the body 101, and first and second substrate wiring pads 107 and 109.

The through hole 101h may penetrate an upper surface 101a and a lower surface 101b. The body 101 may include, for example, at least one material of phenol resin, epoxy resin, and/or polyimide.

For example, the body 101 may include at least one of flame retardant 4 (FR4), tetrafunctional epoxy, polyphenylene ether, epoxy/polyphenylene oxide, bismaleimide triazine (BT), thermount, cyanate ester, polyimide, and/or liquid crystal polymer.

The substrate wiring structure 104 may include a substrate wiring layer 103 and a substrate via 105 connecting the substrate wiring layers 103 to each other. The first and second substrate wiring pads 107 and 109 may include the first substrate wiring pad 107 that is located on the lower surface 101b of the body 101 and electrically connected to the substrate wiring structure 104, and the second substrate wiring pad 109 that is located on the upper surface 101a of the body 101 and electrically connected to the substrate wiring structure 104.

The first substrate wiring pad 107 may include a portion of the substrate wiring layer 103 that is located on the lower surface 101b of the body 101. The second substrate wiring pad 109 may include a portion of the substrate wiring layer 103 that is located on the upper surface 101a of the body 101.

The substrate wiring layer 103, the substrate via 105, and the first and second substrate wiring pads 107 and 10 may include metal layers. For example, the substrate wiring layer 103 and the first and second substrate wiring pads 107 and 109 may include electronically deposited (ED) copper foils, rolled-annealed (RA) copper foils, stainless steel foils, aluminum foils, ultra-thin copper foils, sputtered copper, copper alloys, etc. The substrate via 105 may include, for example, copper, nickel, stainless steel, or beryllium copper.

The semiconductor package 100 may include a semiconductor chip 115 arranged in the through hole 101h. The semiconductor chip 115 may have a fan-in-chip structure. In embodiments of the present inventive concept, the semiconductor chip 115 may correspond to the fan-in region FI of the wiring substrate 106. A body portion of the wiring substrate 106 excluding the through hole 101h may correspond to the fan-out region FO. In embodiments of the present inventive concept, the semiconductor chip 115 may be embedded in the through hole 101h. In the present embodiment, the semiconductor chip 115 may include one chip or a plurality of chips.

In embodiments of the present inventive concept, the semiconductor chip 115 may include individual devices. The individual devices may include various micro-electronic devices, for example, a metal-oxide-semiconductor field effect transistor (MOSFET) such as a complementary metal-insulator-semiconductor (CMOS) transistor, an image sensor, such as a system large scale integration (LSI) (SLSI) sensor, and a CMOS imaging sensor (CIS), a micro-electro-mechanical system (MEMS), an active device, a passive device, etc.

The semiconductor chip 115 may include a logic chip, a power management integrated circuit (PMIC) chip, or a memory chip. In some embodiments, the logic chip may include a memory controller chip, a central processing unit (CPU) chip, a graphics processing unit (GPU) chip, or an application processor (AP) chip.

In embodiments of the present inventive concept, the memory chip may include, for example, a dynamic random access memory (RAM) (DRAM) chip, a static RAM (SRAM) chip, a flash memory chip, an electrically erasable and programmable read-only memory (ROM) (EEPROM) chip, a phase-change RAM (PRAM) chip, a magnetic RAM (MRAM) chip, or a resistive RAM (RRAM) chip.

The semiconductor chip 115 may include a lower surface 115a and an upper surface 115b. The lower surface 115a may include an active surface on which individual elements are formed, and the upper surface 115b may include an inactive surface on which individual elements are not formed. The semiconductor chip 115 may include the lower surface 115a, which is an active surface on which individual elements are formed. The chip pad 117 may be arranged on the lower surface 115a of the semiconductor chip 115. The chip pad 117 may include a metal pad, such as an aluminum pad and a copper pad. The chip pad 117 may include an electrically conductive pad.

The semiconductor package 100 may include a lower redistribution structure 145. The lower redistribution structure 145 may be arranged on the lower surface 101b of the wiring substrate 106 and the lower surface 115a of the semiconductor chip 115. The lower redistribution structure 145 may include a lower redistribution insulating layer 143 and a lower redistribution element 141 which extends to the fan-out region FO of the wiring structure 106 through the lower redistribution insulating layer 143 and is rewired.

The lower redistribution insulating layer 143 may include insulating polymer or a silicon contained insulating material. The insulating polymer may include, for example, photosensitive polyimide (PSPI), polybenzoxazole (PBO), phenolic polymer, and/or benzocyclobutene (BCB)-based polymer. The silicon-contained insulating material may include silicon oxide, silicon nitride, silicon oxynitride, and/or tetraethyl orthosilicate (TEOS).

The lower redistribution element 141 may include a lower redistribution layer 137 and a lower redistribution via 139 that connects to the lower redistribution layer 137. The lower redistribution element 141 may be electrically connected to the chip pad 117 in the fan-in region FI. The lower redistribution element 141 may include the same material as the substrate wiring structure 104.

The lower redistribution structure 145 may include a lower redistribution pad 149 electrically connected to the lower redistribution element 141. The lower redistribution pad 149 may be a portion of the lower redistribution layer 137. The lower redistribution pad 149 may include the same material as that of the first and second substrate wiring pads 107 and 109.

A ball land layer 153, for example, a nickel layer or a copper layer, may be formed on a lower surface of the lower redistribution pad 149. The ball land layer 153 may be formed inside a lower pad insulating layer 151. For example, a portion of the ball land layer 153 may be disposed on a lower surface of the lower pad insulating layer 151. The ball land layer 153 may include a barrier metal layer. For example, the lower redistribution pad 149 and the ball land layer 153 may be in contact with each other.

In embodiments of the present inventive concept, a lower surface of the lower pad insulating layer 151 may be substantially coplanar with the lower surface of the ball land layer 153. The lower redistribution pads 149 may be insulated from each other by the lower pad insulating layer 151. For example, the lower pad insulating layer 151 may be disposed between the lower redistribution pads 149.

The ball land layer 153 may be formed in a ball land hole 156 that is provided in the lower pad insulating layer 151 on the lower redistribution pad 149. A lower solder ball 195 may be formed under the lower surface of the ball land layer 153. The lower solder ball 195 may include a first external connection terminal. In embodiments of the present inventive concept, a capacitor 197 may be arranged in a portion of the ball land layer 153.

In embodiments of the present inventive concept, the lower pad insulating layer 151 may include the same material as that of the lower redistribution insulating layer 143. In embodiments of the present inventive concept, the lower pad insulating layer 151 may include an Ajinomoto build-up film (ABF). The ABF may include epoxy resin, hardener, additive (for example, carbon black), and inorganic filler (for example, silicon oxide).

The semiconductor package 100 may include an encapsulation layer 135. The encapsulation layer 135 may be formed on the semiconductor chip 115, which is embedded in the through hole 101h, and the wiring substrate 106. The encapsulation layer 135 may be formed on both side surfaces of the semiconductor chip 115 in the through hole 101h. The encapsulation layer 135 may at least partially surround the semiconductor chip 115 in the through hole 101h in a plan view. The encapsulation layer 135 may include, for example, an epoxy molding compound (EMC).

The semiconductor package 100 may include an upper redistribution structure 166. The upper redistribution structure 166 may be arranged on the upper surface 101a of the wiring substrate 106 and the upper surface 115b of the semiconductor chip 115. The upper redistribution structure 166 may include an upper redistribution insulating layer 161 and an upper redistribution element 160. The upper redistribution insulating layer 161 may include the same material as that of the lower redistribution insulating layer 143 or that of the lower pad insulating layer 151.

The upper redistribution structure 166 may include an upper redistribution element 160 formed on the encapsulation layer 135. The upper redistribution element 160 may be disposed in the upper redistribution insulating layer 161. For example, adjacent upper redistribution elements 160 may be insulated from each other by the upper redistribution insulating layer 161. The upper redistribution element 160 may include an upper redistribution layer 157 and an upper redistribution via 159. The upper redistribution element 160 may be electrically connected to the substrate wiring structure 104. The upper redistribution element 160 may include the same material as that of the substrate wiring structure 104.

The upper redistribution structure 166 may include an upper redistribution pad 163 electrically connected to the upper redistribution element 160. For example, the upper redistribution pad 163 may be a portion of the upper redistribution layer 157. The upper redistribution pad 163 may be located at the uppermost portion of the upper redistribution layer 157. The upper redistribution pad 163 may be electrically connected to the upper redistribution layer 157. The upper redistribution pad 163 may include the same material as that of the first and second substrate wiring pads 107 and 109.

The semiconductor package 100 may include an upper pad insulating layer 186 and a laser mark metal layer 161. The upper pad insulating layer 186 may cover the upper redistribution layer 157 and the upper redistribution structure 166 including the upper redistribution layer 157 and the upper redistribution insulating layer 161. The laser mark metal layer 183 may be spaced apart from the upper redistribution pad 163 and may be arranged on the upper redistribution insulating layer 161.

The upper pad insulating layer 186 may cover the upper redistribution structure 166 and the laser mark metal layer 183. The upper pad insulating layer 186 may include a laser mark exposure hole 189 that exposes the laser mark metal layer 183.

The upper pad insulating layer 186 may include a transparent insulating layer or a translucent insulating layer. The upper pad insulating layer 186 may include a transparent insulating layer or a translucent insulating layer, through which light transmits. When the upper pad insulating layer 186 includes a transparent insulating layer or a translucent insulating layer, the laser mark metal layer 183 may be seen from the outside. The upper pad insulating layer 186 may include an insulating layer not including carbon black. The upper pad insulating layer 186 may include a yellow-colored material or an amber-colored material.

In embodiments of the present inventive concept, the upper pad insulating layer 186 may include a photo imageable dielectric (PID) layer capable of a photoresist process. In embodiments of the present inventive concept, the PID layer may include a material layer including a polyimide (PI) resin or a polybenzoxazole (PBO) resin. In embodiments of the present inventive concept, the upper pad insulating layer 186 may include a non-PID layer incapable of a photoresist process.

The semiconductor package 100 may include a laser mark metal layer 183 that is exposed by the laser mark exposure hole 189. The laser mark metal layer 183 may be referred to as a laser mark metal pad. The laser mark metal layer 183 may be arranged on the semiconductor chip 115. The upper redistribution pads 163 may be arranged on sides of the laser mark metal layer 183.

The laser mark metal layer 183 may include a dummy metal layer which is not electrically connected to the upper redistribution layer 157. The laser mark metal layer 183 may include a plurality of sub-metal layers. The laser mark metal layer 183 may have a stacked structure in which a first sub-metal layer 165, a second sub-metal layer 179, and a third sub-metal layer 181 are sequentially stacked on the upper redistribution insulating layer 161. The first sub-metal layer 165 may include the same material as that of the upper redistribution pad 163.

In embodiments of the present inventive concept, the first sub-metal layer 165 may include copper (Cu). The second sub-metal layer 179 may include nickel (Ni), and the third sub-metal layer 181 may include gold (Au).

As illustrated in FIG. 2, a width W1 of the first sub-metal layer 165 may be greater than a width W2 of each of the second and third sub-metal layers 179 and 181. The width W2 of each of the second and third sub-metal layers 179 and 181 may be the same as each other. A width W3 of the laser mark exposure hole 189 may be less than the width W2 of each of the second and third sub-metal layers 179 and 181.

As illustrated in FIG. 2, the first sub-metal layer 165 may have a thickness T1. The second sub-metal layer 179 may have a thickness T2. The third sub-metal layer 181 may have a thickness T3. In embodiments of the present inventive concept, the thickness T3 of the third sub-metal layer 181 may be less than each of the thickness T1 of the first sub-metal layer 165 and the thickness T2 of the second sub-metal layer 179. In embodiments of the present inventive concept, the thickness T1 of the first sub-metal layer 165 may be greater than the thickness T2 of the second sub-metal layer 179.

In embodiments of the present inventive concept, the thickness T1 of the first sub-metal layer 165 may be about 1 μm to about 15 μm. In embodiments of the present inventive concept, the thickness T2 of the second sub-metal layer 179 may be about 1 μm to about 10 μm. In embodiments of the present inventive concept, the thickness T3 of the third sub-metal layer 181 may be about 0.1 μm to about 1 μm.

In the semiconductor package 100, a pad exposure hole 187 exposing the upper redistribution pad 163 or a pad metal layer may be formed in the upper pad insulating layer 186. In other words, the upper pad insulating layer 186 may include the pad exposure hole 187 exposing the upper redistribution pad 163 or a pad metal layer 177.

In embodiments of the present inventive concept, the pad metal layer 177 may be arranged on the upper redistribution pad 163. The pad metal layer 177 may be omitted. For example, the upper redistribution pad 163 and the pad metal layer 177 may be arranged at the same level as the laser mark metal layer 183. For example, an upper surface of the pad metal layer 177 may be substantially coplanar with an upper surface of the laser metal layer 183, and the lower surface of the upper redistribution pad 163 may be substantially coplanar with a lower surface of the laser metal layer 183. The total thickness of the upper redistribution pad 163 and the pad metal layer 177 may be the same as a thickness of the laser mark metal layer 183.

The pad metal layer 177 may include a first pad metal layer 173 and a second pad metal layer 175. The first pad metal layer 173 and the second pad metal layer 175 may include the same material as those of the second sub-metal layer 179 and the third sub-metal layer 181, respectively.

The upper pad insulating layer 186 may include a first pad insulating layer 167 that is disposed on the upper redistribution insulating layer 161. For example, the first pad insulating layer 167 may be disposed on the same level as the laser mark metal layer 183. For example, an upper surface of the first pad insulating layer 167 may be substantially coplanar with the upper surface of the pad metal layer 177. The upper pad insulating layer 186 may further include a second pad insulating layer 185 that includes the laser mark exposure hole 189 and is formed on the first pad insulating layer 167.

In other words, the upper pad insulating layer 186 may include the first pad insulating layer 167, which covers the upper redistribution structure 166 and the laser mark metal layer 183, and a second pad insulating layer 185, which includes the laser mark exposure hole 189 and is formed on the first pad insulating layer 167. In embodiments of the present inventive concept, the first pad insulating layer 167 and the second pad insulating layer 185 may include the same material as each other.

As illustrated in FIG. 2, the metal exposure hole 171 exposing the first sub-metal layer 165 may be formed in the first pad insulating layer 167, and the second sub-metal layer 179 and the third sub-metal layer 181 may be formed in the metal exposure hole 171.

The semiconductor package 100 may include a laser mark 193 arranged in the laser mark metal layer 183 that is exposed by the laser mark exposure hole 189. The laser mark 193 may be formed inside the sub-metal layers 165, 179, and 181. In embodiments of the present inventive concept, the laser mark 193 may be formed in the third sub-metal layer 181.

The laser mark 193 may be formed by emitting a laser to a surface of the third sub-metal layer 181. The laser may have a wavelength of several hundred nanometers (nm) and an energy equal to or less than about 1 watt (W). The laser mark 193 may be formed in an intaglio shape on the surface of the third sub-metal layer 181. The laser mark 193 may have a depth D1 of several nanometers (nm). The laser mark 193 may have a black color.

Although the semiconductor package 100 according to an embodiment of the present inventive concept includes both the lower redistribution structure 145 and the upper redistribution structure 166, the semiconductor package 100 may include only one of the lower redistribution structure 145 or the upper redistribution structure 166 according to an embodiment of the present inventive concept.

For example, when the semiconductor package 100 does not include the lower redistribution structure 145, the lower solder ball 195 may be directly connected to the first substrate wiring pad 107. When the semiconductor package 100 does not include the upper redistribution structure 166, the second substrate wiring pad 109 may be exposed, and the laser mark metal layer 183 and the upper pad insulating layer 186 may be arranged on the encapsulation layer 135.

Because the semiconductor package 100 according to an embodiment of the present inventive concept includes a transparent or translucent upper pad insulating layer 186 capable of preventing damage to the upper redistribution layer 157 and the upper redistribution insulating layer 161, damage to the upper redistribution layer 157 and the upper redistribution insulating layer 161 may be prevented.

The semiconductor package 100 according to an embodiment of the present inventive concept may include the laser mark exposure hole 189 which exposes the laser mark metal layer 183 by opening a portion of the transparent or translucent upper pad insulating layer 186. Accordingly, because the semiconductor package 100 according to an embodiment of the present inventive concept forms the laser mark 193 on the laser mark metal layer 183 in the laser mark exposure hole 189, the visibility of the laser mark 193 may be increased.

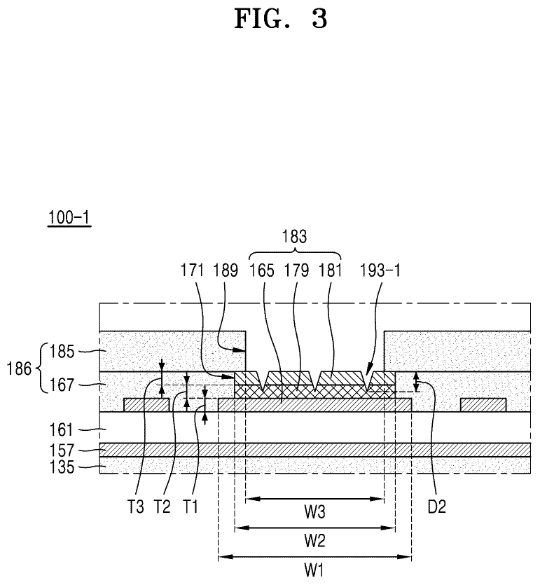

FIG. 3 is a cross-sectional view of components of a semiconductor package 100-1, according to an embodiment of the present inventive concept.

The semiconductor package 100-1 may be the same as the semiconductor package 100 of FIGS. 1 and 2, except that a laser mark 193-1 is different from the laser mark 193 of FIG. 2. FIG. 3 may be a modified embodiment of the enlarged view of FIG. 2. In FIG. 3, the identical reference numerals as those in FIGS. 1 and 2 may represent the identical members. In FIG. 3, duplicate descriptions given with reference to FIGS. 1 and 2 are briefly provided or omitted.

The semiconductor package 100-1 may include the laser mark 193-1 formed in the laser mark metal layer 183 exposed by the laser mark exposure hole 189. The laser mark metal layer 183 may have a stacked structure in which a first sub-metal layer 165, a second sub-metal layer 179, and a third sub-metal layer 181 are sequentially stacked on the upper redistribution insulating layer 161.

The laser mark 193-1 may be formed inside the sub-metal layers 165, 179, and 181. In embodiments of the present inventive concept, the laser mark 193-1 may be formed in the third sub-metal layer 181 and the second sub-metal layer 179. The laser mark 193-1 may be formed by emitting a laser to the third sub-metal layer 181 and the second sub-metal layer 179. The laser may have a wavelength of several hundred nanometers (nm) and an energy equal to or greater than about 1 watt (W). The laser mark 193-1 may be formed in an intaglio shape on the surface of the third sub-metal layer 181. The laser mark 193-1 may have a depth D2 of several nanometers (nm). The laser mark 193-1 may have a white color.

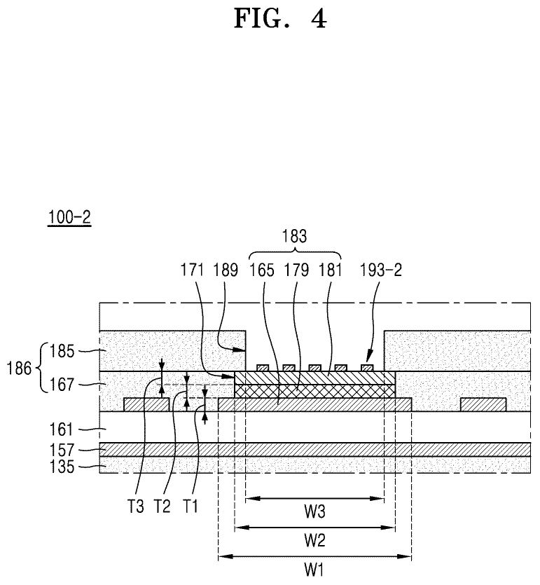

FIG. 4 is a cross-sectional view of components of a semiconductor package 100-2, according to an embodiment of the present inventive concept.

The semiconductor package 100-2 may be the same as the semiconductor package 100 of FIGS. 1 and 2, except that a laser mark 193-2 is different from the laser mark 193 of FIG. 2. FIG. 4 may be a modified embodiment of the enlarged view of FIG. 2. In FIG. 4, the identical reference numerals as those in FIGS. 1 and 2 may represent the identical members. In FIG. 4, duplicate descriptions given with reference to FIGS. 1 and 2 are briefly provided or omitted.

The semiconductor package 100-2 may include the laser mark 193-2 formed in the laser mark metal layer 183 exposed by the laser mark exposure hole 189. The laser mark metal layer 183 may have a stacked structure in which the first sub-metal layer 165, the second sub-metal layer 179, and the third sub-metal layer 181 are sequentially stacked on the upper redistribution insulating layer 161.

The laser mark 193-2 may be formed on the surface of the third sub-metal layer 181 at the uppermost portion among the sub-metal layers 165, 179, and 181. In embodiments of the present inventive concept, the laser mark 193-2 may be formed on the surface of the third sub-metal layer 181. The laser mark 193-2 may be formed by emitting a laser to the surface of the third sub-metal layer 181. The laser may have a wavelength of several hundred nanometers (nm) and an energy equal to or less than about 1 watt (W). The laser mark 193-2 may be in a state in which a fine oxide layer is formed on the surface of the third sub-metal layer 181. The laser mark 193-2 may be formed by oxidizing the surface of the third sub-metal layer 181. The laser mark 193-2 may have a black color.

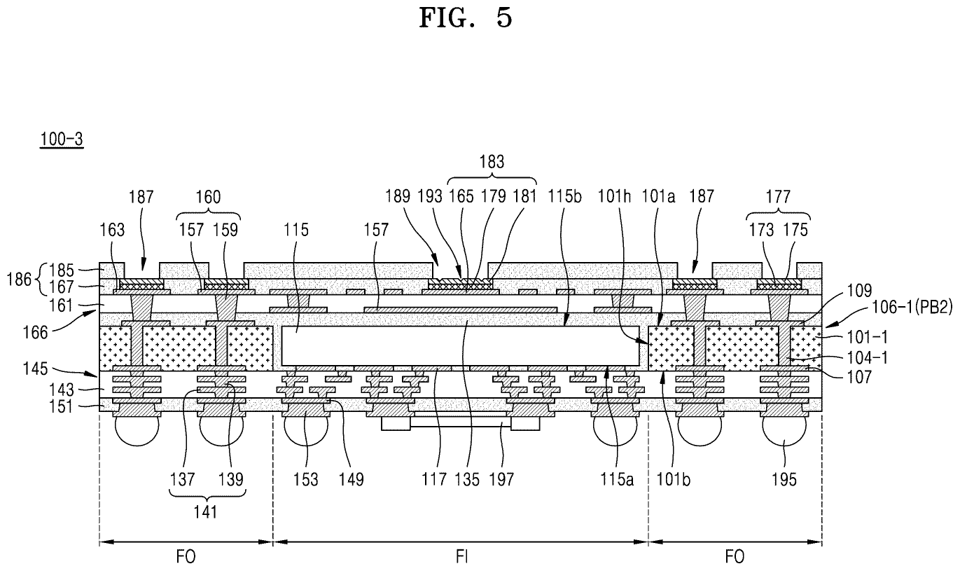

FIG. 5 is a cross-sectional view of components of a semiconductor package 100-3, according to an embodiment of the present inventive concept.

The semiconductor package 100-3 may be the same as the semiconductor package 100 of FIGS. 1 and 2, except that a wiring substrate 106-1 is different from the wiring substrate 106 of FIG. 1. In FIG. 5, the identical reference numerals as those in FIGS. 1 and 2 may represent the identical members. In FIG. 5, duplicate descriptions given with reference to FIGS. 1 and 2 are briefly provided or omitted.

The semiconductor package 100-3 may include the wiring substrate 106-1. The wiring substrate 106-1 may include a package body PB2. The package body PB2 may include a package element. The wiring substrate 106-1 may include a semiconductor substrate.

The semiconductor package 100-3 may include a package of a fan-out wafer level package (FOWLP) form. The wiring substrate 106-1 may include a body 101-1, a substrate wiring structure 104-1 located in the body 101-1, and the substrate wiring pads 107 and 109.

The body 101-1 may include a semiconductor element such as germanium (Ge), or a compound semiconductor, such as silicon carbide (SiC), gallium arsenide (GaAs), indium arsenide (InAs), and indium phosphide (InP). The substrate wiring structure 104-1 may include a substrate wiring layer formed in the body 101-1. The substrate wiring layer 103 may include a metal layer, for example, a copper layer. In this manner, the semiconductor package 100-3 may use a semiconductor substrate as the wiring substrate 106-1.

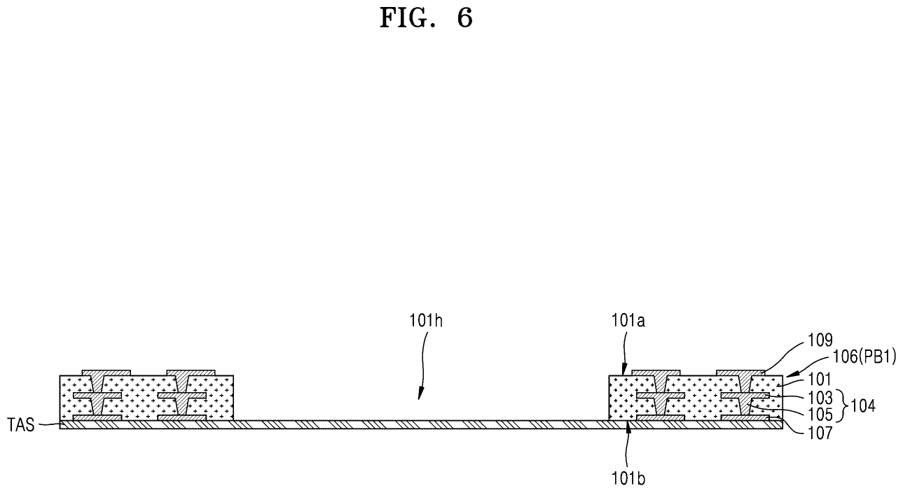

FIGS. 6 through 17 are cross-sectional views of components for describing a manufacturing method of the semiconductor package 100 of FIGS. 1 and 2, according to an embodiment of the present inventive concept.

In the description with respect to FIGS. 6 through 17, identical reference numerals as those in FIGS. 1 through 7 may represent identical members. In FIGS. 6 through 17, duplicate descriptions given with reference to FIGS. 1 and 2 are briefly provided or omitted.

Referring to FIG. 6, the wiring substrate 106 including the through hole 101h may be prepared. The wiring substrate 106 may constitute the package body PB1. The wiring substrate 106 may include an insulating substrate. The wiring substrate 106 may include the body 101 located on both sides of the through hole 101h, the substrate wiring structure 104 formed in the body 101, and the first and second substrate wiring pads 107 and 109.

The substrate wiring structure 104 may include a substrate wiring layer 103 and a substrate via 105 connecting the substrate wiring layers 103 to each other. The first and second substrate wiring pads 107 and 109 may include the first substrate wiring pad 107 located on the lower surface 101b of the body 101, and the second substrate wiring pad 109 located on the upper surface 101a of the body 101. The first substrate wiring pad 107 may include a portion of the substrate wiring layer 103 that is located on the lower surface 101b of the body 101. The second substrate wiring pad 109 may include a portion of the substrate wiring layer 103 that is located on the upper surface 101a of the body 101.

Next, the wiring substrate 106, in which the through hole 101h is formed, may be attached onto a tape substrate TAS. The wiring substrate 106 may be attached to the tape substrate TAS so that the first substrate wiring pad 107 that is located on the lowermost surface of the wiring substrate 106 is attached to the tape substrate TAS. As a result, the through hole 101h may be located at the central portion of the tape substrate TAS, and the body 101 may be located on both sides of the tape substrate TAS.

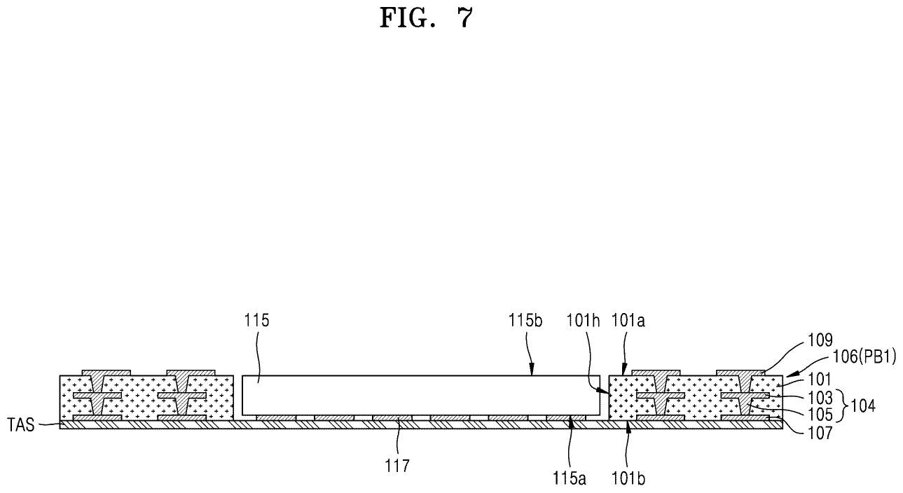

Referring to FIG. 7, the semiconductor chip 115 may be attached to the tape substrate TAS with the chip pad 117 downward in the through hole 101h of the wiring substrate 106. The semiconductor chip 115 may be attached to the tape substrate TAS with an active surface, that is, the lower surface 115a, on which the chip pad 117 is formed.

As a result, the semiconductor chip 115 may be located in the through hole 101h. When the semiconductor chip 115 is attached to the tape substrate TAS, the semiconductor chip 115 may be located apart from one side surface of the wiring substrate 106.

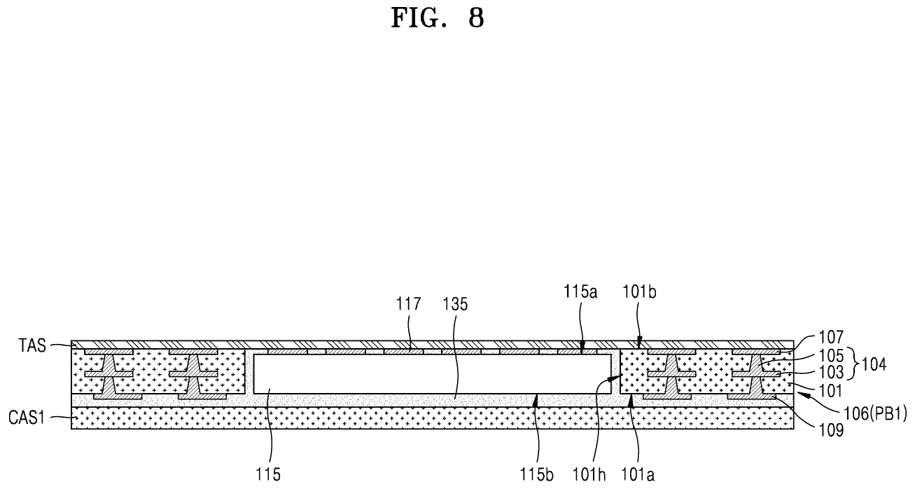

Referring to FIG. 8, for convenience, FIG. 8 is a view illustrating the tape substrate TAS as located on the upper side after the structure of FIG. 7 is inverted. The encapsulation layer 135 sealing the semiconductor chip 115 and the wiring substrate 106 may be formed on the tape substrate TAS.

The encapsulation layer 135 may be formed to be thick to sufficiently seal the semiconductor chip 115 and the wiring substrate 106. The encapsulation layer 135 may be formed to be thicker than the upper surface 101a of the body 101 and the upper surface 115b of the semiconductor chip 115. Next, a first carrier substrate CAS1 may be attached onto the encapsulation layer 135. The first carrier substrate CAS1 may include an insulating substrate or a semiconductor substrate.

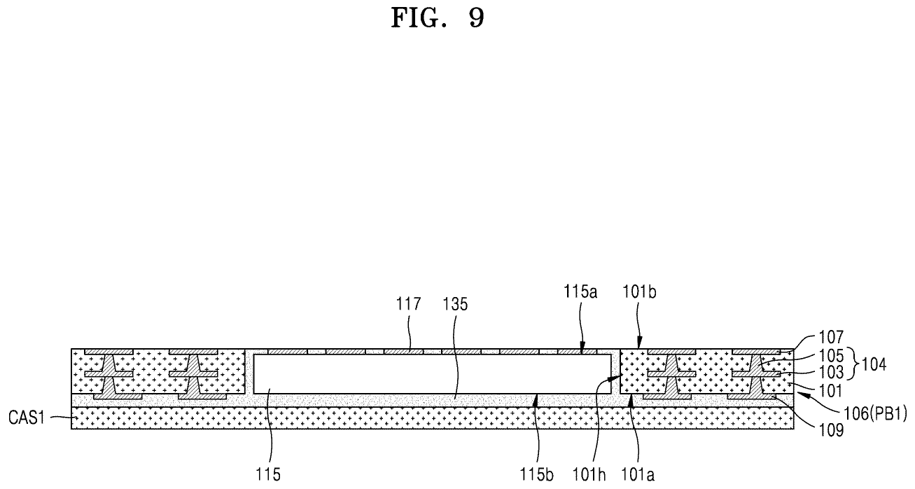

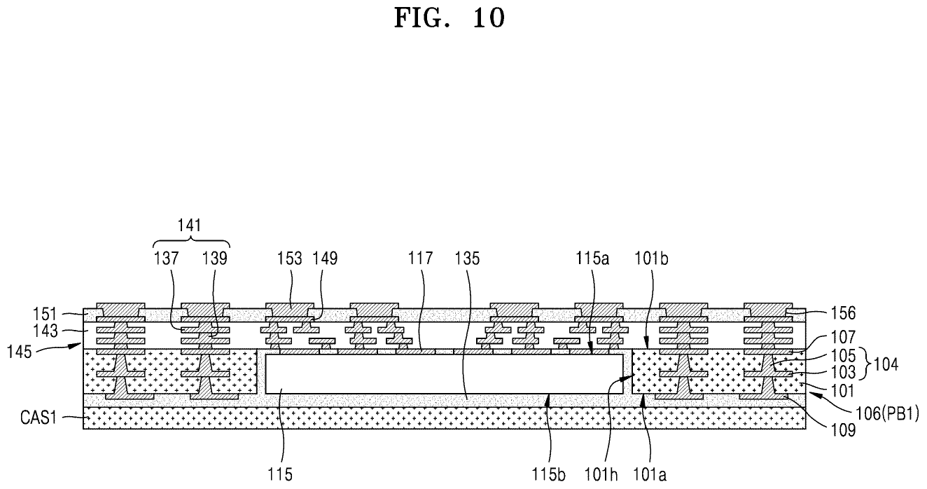

Referring to FIGS. 9 and 10, the tape substrate (TAS in FIG. 8) may be removed as illustrated in FIG. 9. Next, as illustrated in FIG. 10, the lower redistribution structure 145 may be formed on the lower surface 115a of the semiconductor chip 115 and the lower surface 101b of the wiring substrate 106. The lower redistribution structure 145 may be arranged on the lower surface 101b of the wiring substrate 106 and the lower surface 115a of the semiconductor chip 115.

The lower redistribution structure 145 may include the lower redistribution insulating layer 143, the lower redistribution element 141, and the lower redistribution pad 149. The lower redistribution element 141 may include the lower redistribution layer 137 and the lower redistribution via 139 connecting to the lower redistribution layer 137. The lower redistribution element 141 may be electrically connected to the chip pad 117. The lower redistribution structure 145 may extend to the fan-out region (FO in FIG. 1) to be electrically connected to the first substrate wiring pad 107.

The lower redistribution pad 149 and the lower pad insulating layer 151 may be formed on the lower redistribution structure 145. In embodiments of the present inventive concept, the lower pad insulating layer 151 may include the ABF. The lower redistribution pad 149 may be electrically connected to the lower redistribution structure 145. The lower redistribution pad 149 may include a portion of the lower redistribution layer 137 that is located on an upper surface of the lower redistribution insulating layer 143.

Next, the ball land hole 156 may be formed in the lower pad insulating layer 151 on the lower redistribution pad 149, and the ball land layer 153 may be formed in the ball land hole 156.

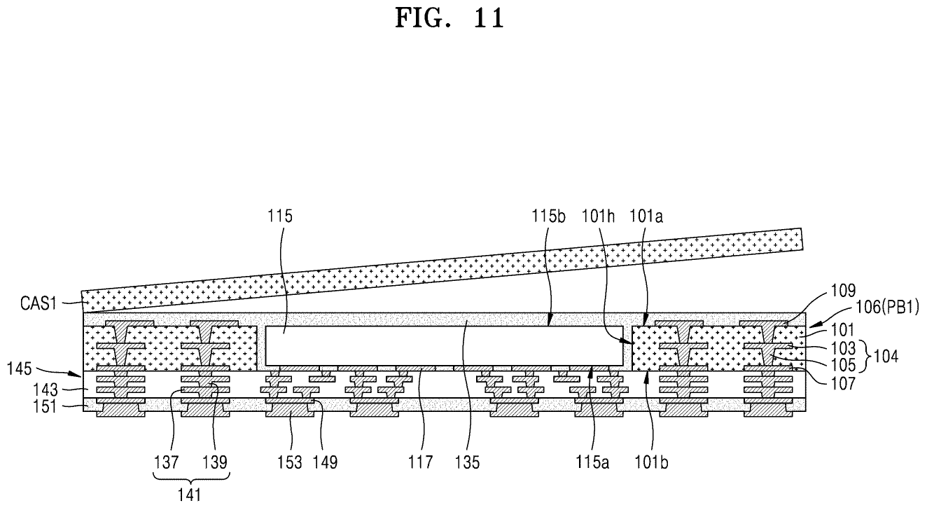

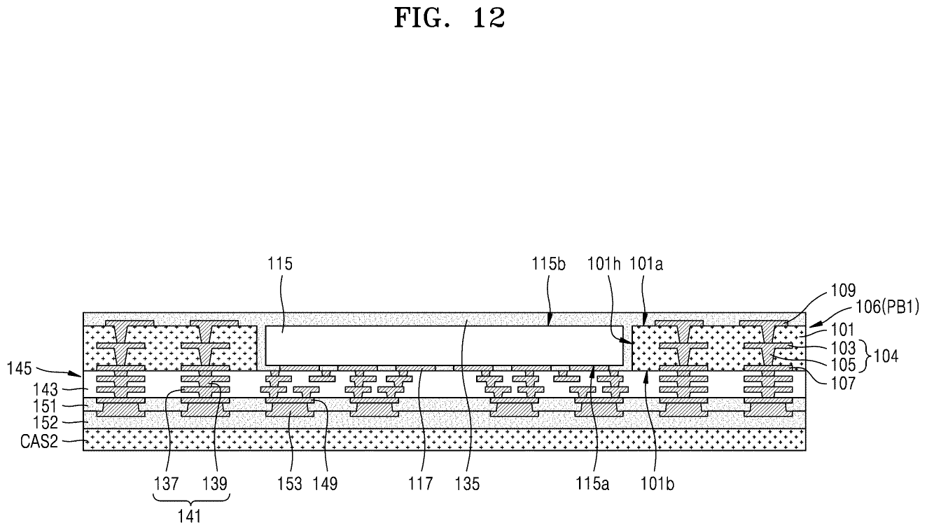

Referring to FIGS. 11 and 12, the first carrier substrate (CAS1 in FIG. 10) formed on the encapsulation layer 135 may be removed as illustrated in FIG. 11. FIG. 11 is an inverted view of the structure of FIG. 10.

As illustrated in FIG. 12, an additional lower pad insulating layer 152 may be formed on the ball land layer 153 and the lower pad insulating layer 151, and then a second carrier substrate CAS2 may be attached onto the additional lower pad insulating layer 152. The additional lower pad insulating layer 152 may include the same material as that of the lower pad insulating layer 151. For example, the additional lower pad insulating layer 152 may be omitted. The second carrier substrate CAS2 may include an insulating substrate or a semiconductor substrate.

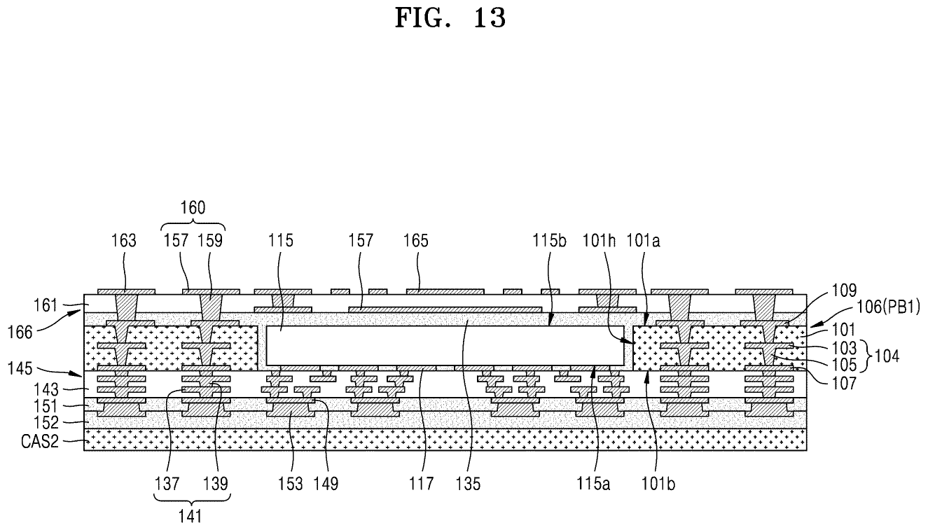

Referring to FIG. 13, the upper redistribution structure 166 may be formed on the upper surface 101a of the wiring substrate 106 and the upper surface of the semiconductor chip 115. The upper redistribution structure 166 may include an upper redistribution element 160 formed on the encapsulation layer 135, and adjacent upper redistribution elements 160 may be insulated from each other by the upper redistribution insulating layer 161. The upper redistribution element 160 may include an upper redistribution layer 157 and an upper redistribution via 159.

The upper redistribution layer 157 may extend to the fan-out region (FO in FIG. 1) in a plan view and be rewired. The upper redistribution structure 166 may include the upper redistribution pad 163 that is electrically connected to the upper redistribution element 160. The upper redistribution pad 163 may be a portion of the upper redistribution layer 157. The upper redistribution pad 163 may be electrically separated by the upper redistribution insulating layer 161.

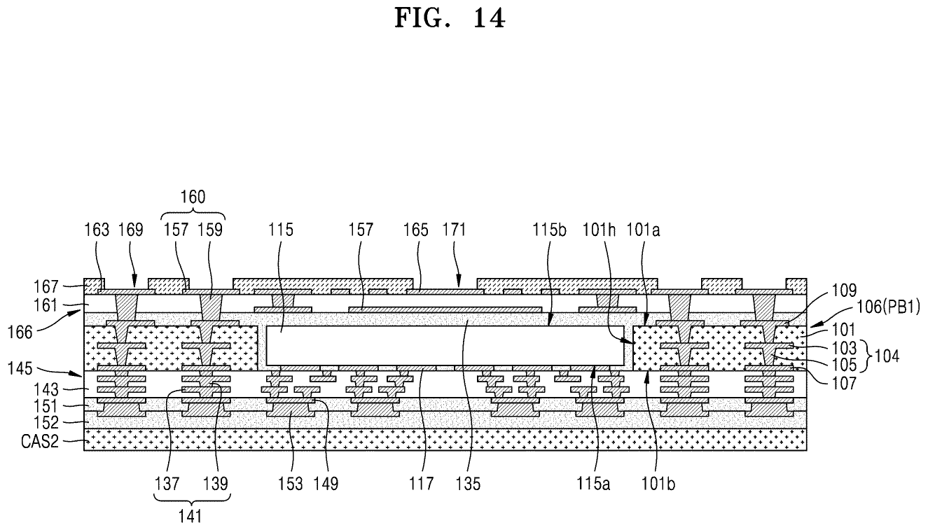

Referring to FIG. 14, a first pad insulating material layer may be formed on the upper redistribution pad 163, the first sub-metal layer 165, and the upper redistribution insulating layer 161, and then may be patterned to form the first pad insulating layer 167. The first pad insulating material layer may be formed on a structure in which the upper redistribution pad 163, the first sub-metal layer 165, and the upper redistribution insulating layer 161 are formed, and then may be patterned to form the first pad insulating layer 167.

By patterning the first pad insulating material layer, a first pad exposure hole 169, which exposes the upper redistribution pad 163, and the metal exposure hole 171, which exposes the first sub-metal layer 165, may be formed in the first pad insulating layer 167. The first pad insulating material layer may be formed of a transparent insulating layer or a translucent insulating layer. The first pad insulating material layer may include an insulating layer in which carbon black is not included. The first pad insulating material layer may include a yellow material or amber material.

When the first pad insulating material layer is formed of the PID layer capable of a photoresist process, the first pad exposure hole 169 and the metal exposure hole 171 may be formed by using a photoresist process. When the first pad insulating material layer is formed of a non-PID layer that is not capable of a photoresist process, the first pad exposure hole 169 and the metal exposure hole 171 may be formed by using a laser process.

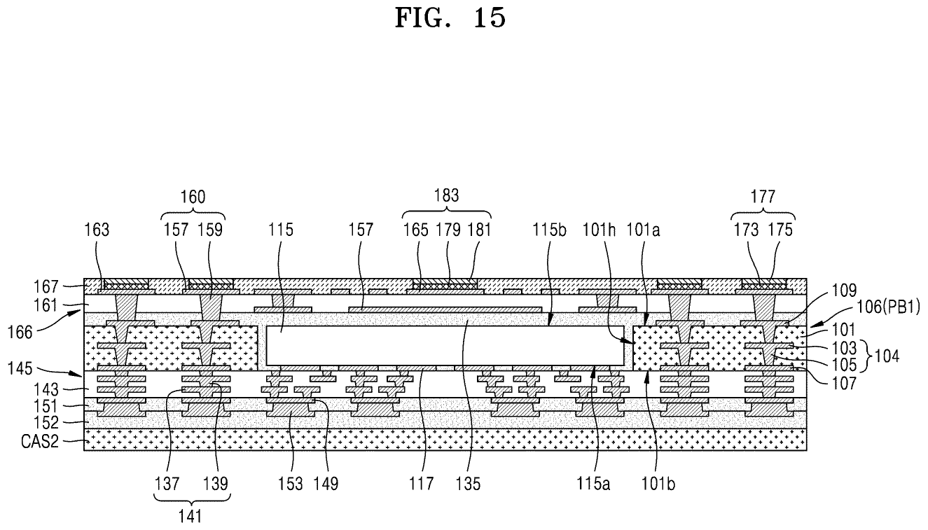

Referring to FIG. 15, the pad metal layer 177 may be formed in the first pad exposure hole 169. The second and third sub-metal layers 179 and 181 may be formed in the metal exposure hole 171. The pad metal layer 177 and the second and third sub-metal layers 179 and 181 may be formed by using the same process.

The pad metal layer 177 may include the first pad metal layer 173 and the second pad metal layer 175. The first pad metal layer 173 and the second pad metal layer 175 may include the same material as those of the second sub-metal layer 179 and the third sub-metal layer 181, respectively.

The laser mark metal layer 183 may be formed by sequentially forming the second sub-metal layer 179 and the third sub-metal layer 181 on the first sub-metal layer 165. The upper redistribution pad 163 and the pad metal layer 177 may be formed at the same level as the laser mark metal layer 183. For example, an upper surface of the pad metal layer 177 may be substantially coplanar with an upper surface of the laser metal layer 183, and the lower surface of the upper redistribution pad 163 may be substantially coplanar with a lower surface of the laser metal layer 183.

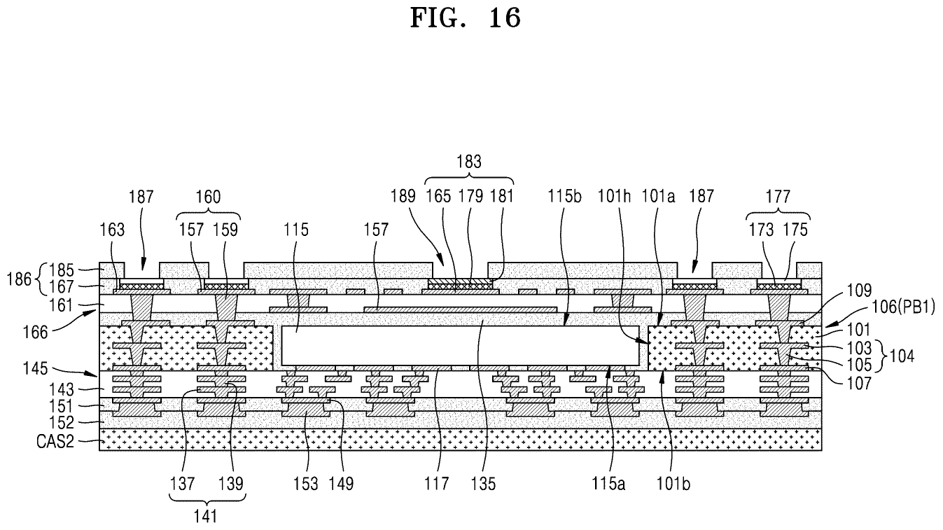

Referring to FIG. 16, a second pad insulating material layer may be formed on the first pad insulating layer 167, the pad metal layer 177, and the laser mark metal layer 183, and then, may be patterned to form the second pad insulating layer 185. The second pad insulating material layer may be formed on structure in which the first pad insulating layer 167, the pad metal layer 177, and the laser mark metal layer 183 are formed, and then, may be patterned to form the second pad insulating layer 185.

By patterning the second pad insulating material layer, a second pad exposure hole 187, which exposes the pad metal layer 177, and the laser mark exposure hole 189, which exposes the third sub-metal layer 181, may be formed in the second pad insulating layer 185.

The second pad insulating material layer may be formed of a transparent insulating layer or a translucent insulating layer. The second pad insulating material layer may include an insulating layer in which carbon black is not included. The second pad insulating material layer may include a yellow material or amber material.

When the second pad insulating material layer is formed of the PID layer capable of a photoresist process, the second pad exposure hole 187 and the laser mark exposure hole 189 may be formed by using a photoresist process. When the second pad insulating material layer is formed of a non-PID layer that is not capable of a photoresist process, the second pad exposure hole 187 and the laser mark exposure hole 189 may be formed by using a laser process.

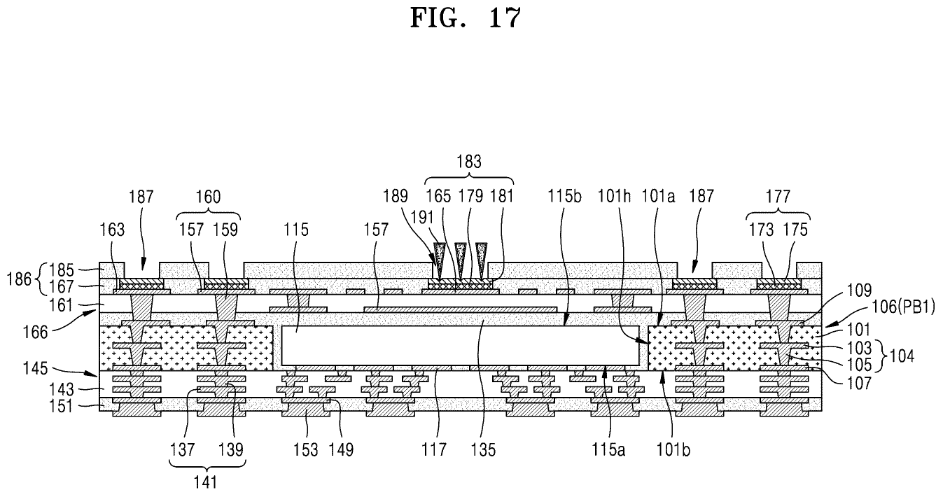

Referring to FIG. 17, the laser mark (193 in FIG. 1) may be formed by emitting a laser to the laser mark metal layer 183 that is exposed by the laser mark exposure hole 189. The laser mark (193 in FIG. 1) may be formed inside the sub-metal layers 165, 179, and 181.

The laser mark 193 may be formed in the third sub-metal layer 181. The laser mark 193 may be formed by emitting a laser to the surface of the third sub-metal layer 181. A laser may have a wavelength of several hundred nanometers (nm) and an energy equal to or less than about 1 watt (W). The laser mark 193 may have a depth of several nanometers (nm) on the surface of the third sub-metal layer 181. The laser mark 193 may have a black color.

Next, the second carrier substrate (CAS2 in FIG. 16) may be removed. Next, after the additional lower pad insulating layer 152 is removed, as illustrated in FIG. 1, the lower solder ball 195 may be formed on the ball land layer 153. As a result, the semiconductor package 100 illustrated in FIGS. 1 and 2 may be manufactured.

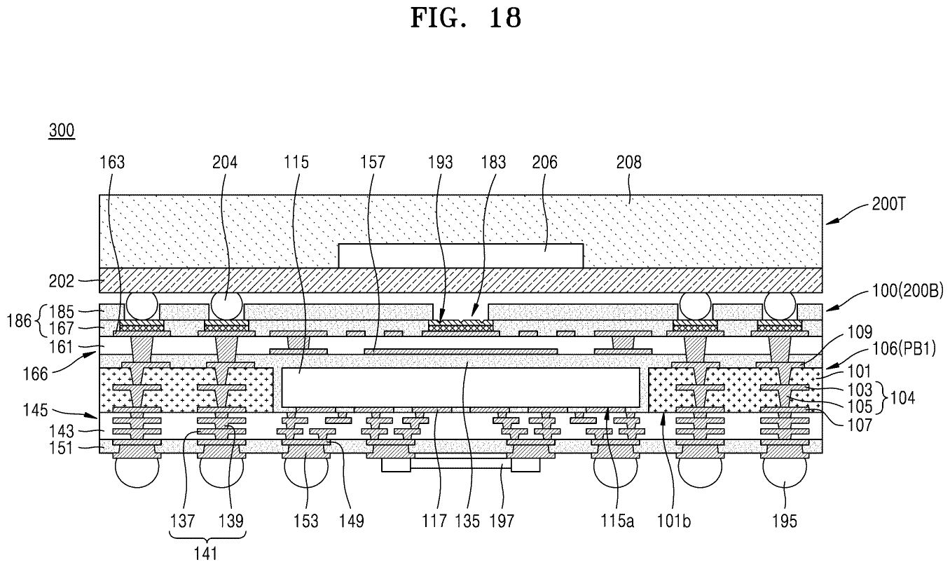

FIG. 18 is a cross-sectional view of a semiconductor package 300, according to an embodiment of the present inventive concept.

The semiconductor package 300 may be the same as the semiconductor package 100 of FIGS. 1 and 2, except that the semiconductor package 300 incudes a stacked package including an upper package 200T further stacked thereon. In FIG. 18, identical reference numerals as those in FIGS. 1 and 2 may represent the identical members. In FIG. 18, duplicate descriptions given with reference to FIGS. 1 and 2 are briefly described or omitted. In this case, the semiconductor package 100 of FIGS. 1 and 2 may be renamed as a lower package 200B.

The semiconductor package 300 may include a stack package including the lower package 200B and the upper package 200T. An upper solder ball 204 may be connected to the upper redistribution pad 163 of the lower package 200B. The upper solder ball 204 may include a second external connection terminal. The upper package 200T may be attached onto the upper solder ball 204.

The upper package 200T may include an upper semiconductor chip 206 attached onto an upper wiring substrate 202. The upper wiring substrate 202 and the upper semiconductor chip 206 may be electrically connected to each other via a bonding wire or a bump. In FIG. 18, the upper semiconductor chip 206 may be connected to the upper wiring substrate 202 by using a bump. The upper semiconductor chip 206 may include a memory chip. Examples of the memory chip may be the same as those described above.

The upper package 200T may include an upper encapsulation layer 208 at least partially surrounding at least a portion of the upper semiconductor chip 206. The upper encapsulation layer 208 may include, for example, an EMC. Although the upper encapsulation layer 208 is illustrated to cover an inactive surface (e.g., the upper surface) of the upper semiconductor chip 206, the present inventive concept is not limited thereto.

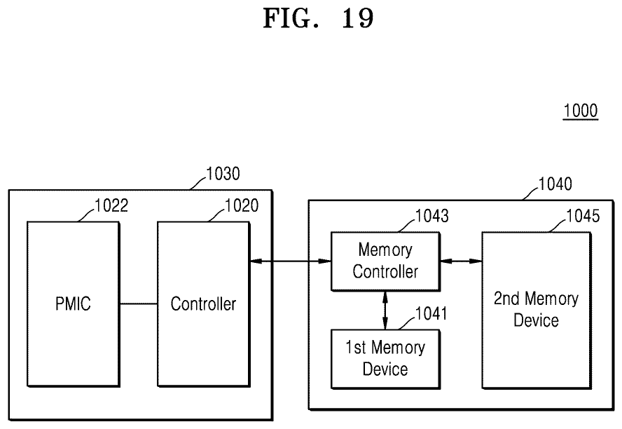

FIG. 19 is a block diagram of a configuration of a semiconductor package 1000, according to an embodiment of the present inventive concept.

The semiconductor package 1000 may include a controller device 1020 (or, e.g., a controller chip), a first memory device 1041 (or, e.g., a first memory chip), a second memory device 1045 (or, e.g., a second memory chip), and a memory controller device 1043 (or, e.g., a memory controller chip). The semiconductor package 1000 may further include a PMIC device 1022 (or, e.g., a power management chip) which supplies a current of an operating voltage to each of the controller device 1020, the first memory device 1041, the second memory device 1045, and the memory controller device 1043. The operating voltages that are respectively applied to components may be designed to be the same as or different from each other.

The semiconductor package 1000 may include the semiconductor packages 100, 100-1, 100-2, 100-3, and 300 according to an embodiment of the present inventive concept. In embodiments of the present inventive concept, a lower package 1030 including the controller device 1020 and the PMIC 1022 may include the lower package 200B according to an embodiment of the present inventive concept described above. The lower package 200B may include the semiconductor packages 100, 100-1, 100-2, and 100-3 described above. An upper package 1040 including the first memory device 1041, the second memory device 1045, and the memory controller device 1043 may include the upper package 200T according to an embodiment of the present inventive concept described above.

The semiconductor package 1000 may be implemented to be included in, for example, a personal computer (PC) or a mobile device. The mobile device may be implemented as a laptop computer, a mobile phone, a smartphone, tablet PCs, a personal digital assistant (PDA), an enterprise digital assistant (EDA), a digital still camera, a digital video camera, a portable multimedia player (PMP), a personal navigation device or a portable navigation device (PND), a handheld game console, a mobile Internet device (MID), a wearable computer, an Internet of Things (IoT) device, an Internet of Things (IoE) device, or a drone.

The controller device 1020 may control an operation of each of the first memory device 1041, the second memory device 1045, and the memory controller device 1043. For example, the controller device 1020 may be implemented as an integrated circuit (IC), a system on chip (SoC), an AP, a mobile AP, a chipset, or a set of chips. The controller device 1020 may include a CPU, a GPU, and/or a modem. In embodiments of the present inventive concept, the controller device 1020 may perform functions of a modem and functions of an AP.

The memory controller device 1043 may control the second memory device 1045 under the control of the controller device 1020. The first memory device 1041 may be implemented as a volatile memory device. The volatile memory device may be implemented as RAM, DRAM, or SRAM, but the present inventive concept is not limited thereto. The second memory device 1045 may be implemented as a storage memory device. The storage memory device may be implemented as a non-volatile memory device.

The storage memory device may be implemented as a flash-based memory device, but the present inventive concept is not limited thereto. The second memory device 1045 may be implemented as a NAND-type flash memory device. The NAND-type flash memory device may include a two-dimensional memory cell array or a three-dimensional memory cell array. The two-dimensional memory cell array or the three-dimensional memory cell array may include a plurality of memory cells, and each of the plurality of memory cells may store 1-bit information or 2-bit or more information.

When the second memory device 1045 is implemented as a flash-based memory device, the memory controller device 1043 may use (or support) a multimedia card interface (MMC) interface, an embedded MMC (eMMC)) interface, or a universal flash storage (UFS) interface, but the present inventive concept is not limited thereto.

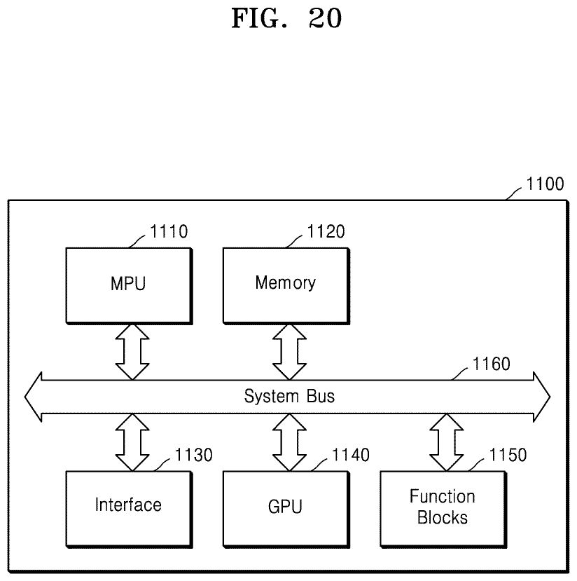

FIG. 20 is a schematic block diagram of a configuration of a semiconductor package 1100, according to an embodiment of the present inventive concept.

The semiconductor package 1100 may include a micro-processing unit (MPU) 1110 (or, e.g., a micro-processing unit chip), a memory 1120 (or, e.g., a memory chip), an interface 1130, a graphic processing unit (GPU) 1140 (or, e.g., a graphic processing chip), functional blocks 1150, and a system bus 1160 connecting the previously mentioned components to each other. The semiconductor package 1100 may include both the MPU 1110 and the GPU 1040, or may also include only one of the two components.

The MPU 1110 may include a core and an L2 cache. For example, the MPU 1110 may include a multi-core. Each core of the multi-core may be the same as or different from each other. In addition, each core of the multi-core may be simultaneously activated, or may have different time point of activation. The memory 1120 may store a result processed by the functional blocks 1150 under the control of the MPU 1110. For example, the MPU 1110 may be stored in the memory 1120 as the content stored in the L2 cache thereof is flushed. The interface 1130 may perform an interfacing process with external devices. For example, the interface 1130 may perform an interface with a camera, a liquid crystal display (LCD), a speaker, etc.

The GPU 1140 may perform graphic functions. For example, the GPU 1140 may perform a video codec, or process a three-dimensional (3D) graphics. The function blocks 1150 may perform various functions. For example, when the semiconductor package 1100 includes an AP used for a mobile device, some of the functional blocks 1150 may perform a communication function.

The semiconductor package 1100 may include the semiconductor packages 100, 100-1, 100-2, 100-3, and 300 according to embodiments of the present inventive concept. In embodiments of the present inventive concept, the micro-processing unit 1110 and/or the GPU 1140 may include the lower package 200B illustrated above. In embodiments of the present inventive concept, the memory 1120 may include the upper package 200T illustrated above. The interface 1130 and the functional blocks 1150 may correspond to a portion of the lower package 200B illustrated above.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
an encapsulation layer configured to seal at least one semiconductor chip;
a redistribution structure arranged on the encapsulation layer, wherein the redistribution structure includes a redistribution metal layer and a redistribution insulating layer disposed on the redistribution metal layer, and the redistribution metal layer includes a redistribution pad formed at an upper portion thereof;
a laser mark metal layer spaced apart from the redistribution pad and arranged on the redistribution insulating layer;
a pad insulating layer configured to cover the redistribution structure and the laser mark metal layer, wherein the pad insulating layer includes a transparent insulating layer or a translucent insulating layer, and includes a laser mark exposure hole exposing the laser mark metal layer; and
a laser mark arranged inside or on a surface of the laser mark metal layer that is exposed by the laser mark exposure hole.

2. The semiconductor package of claim 1, wherein the pad insulating layer further comprises a pad exposure hole exposing the redistribution pad.

3. The semiconductor package of claim 2, wherein a pad metal layer is arranged on the redistribution pad, and the redistribution pad is disposed at substantially a same level as the laser mark metal layer.

4. The semiconductor package of claim 3, wherein the pad insulating layer comprises a first pad insulating layer and a second pad insulating layer, wherein the first pad insulating layer is disposed at substantially a same level as the redistribution pad and the laser mark metal layer, and the second pad insulating layer includes the laser mark exposure hole that is formed therein and is disposed on the first pad insulating layer.

5. The semiconductor package of claim 1, wherein the laser mark metal layer is arranged on the semiconductor chip, and the redistribution pad is arranged on sides of the laser mark metal layer.

6. The semiconductor package of claim 1, wherein the laser mark metal layer comprises a plurality of sub-metal layers, and the laser mark are arranged in the plurality of sub-metal layers.

7. The semiconductor package of claim 1, wherein the laser mark metal layer comprises a plurality of sub-metal layers, and the laser mark is arranged on a surface of an uppermost sub-metal layer among the plurality of sub-metal layers.

8. The semiconductor package of claim 1, wherein the laser mark metal layer is a dummy metal layer that is not electrically connected to the redistribution metal layer.

9. The semiconductor package of claim 3, wherein the pad insulating layer comprises a first pad insulating layer and a second pad insulating layer, wherein the first pad insulating layer is configured to cover the redistribution structure and the laser mark metal layer, and the second pad insulating layer includes the laser mark exposure hole that is formed therein and is disposed on the first pad insulating layer.

10. A semiconductor package comprising:
a package body having a fan-in region and a fan-out region at least partially surrounding the fan-in region, wherein a substrate wiring structure is arranged in the package body and in the fan-out region;
a semiconductor chip arranged in the fan-in region;
an encapsulation layer configured to seal the semiconductor chip and the package body;
a redistribution structure arranged on the encapsulation layer and electrically connected to the substrate wiring structure, wherein the redistribution structure includes a redistribution metal layer and a redistribution insulating layer configured to insulate the redistribution metal layer, and the redistribution metal layer incudes a redistribution pad formed at an upper portion thereof;
a laser mark metal layer spaced apart from the redistribution pad and arranged on the redistribution insulating layer;
a pad insulating layer configured to cover the redistribution structure and the laser mark metal layer, wherein the pad insulating layer includes a transparent insulating layer or a translucent insulating layer, and the pad insulating layer includes a laser mark exposure hole exposing the laser mark metal layer; and
a laser mark arranged inside or on a surface of the laser mark metal layer that is exposed by the laser mark exposure hole.

11. The semiconductor package of claim 10, wherein the laser mark metal layer is a stacked structure in which a first sub-metal layer, a second sub-metal layer, and a third sub-metal layer are sequentially stacked on the redistribution insulating layer.

12. The semiconductor package of claim 11, wherein the laser mark is arranged inside the first sub-metal layer, inside the second sub-metal layer, or on a surface of the third sub-metal layer.

13. The semiconductor package of claim 11, wherein a width of the first sub-metal layer is greater than widths of the second sub-metal layer and the third sub-metal layer, wherein the width of the second sub-metal layer and the width of the third sub-metal layer are identical to each other, and a width of the laser mark exposure hole is less than the width of the third sub-metal layer.

14. The semiconductor package of claim 10, wherein the pad insulating layer further comprises a pad exposure hole configured to expose the redistribution pad, wherein a pad metal layer is arranged on the redistribution pad, and the redistribution pad is arranged at an identical level as the laser mark metal layer.

15. The semiconductor package of claim 10, wherein the pad insulating layer comprises a first pad insulating layer and a second pad insulating layer, wherein the first pad insulating layer is configured to cover the redistribution structure and the laser mark metal layer, and the second pad insulating layer includes the laser mark exposure hole formed therein and is disposed on the first pad insulating layer.

16. The semiconductor package of claim 10, wherein the package body comprises a wiring substrate, and the wiring substrate comprises an insulating substrate or a semiconductor substrate.

17. The semiconductor package of claim 10, wherein the package body comprises a through hole, in which the semiconductor chip is mounted, at a central portion thereof, and the substrate wiring structure is arranged in the package body and at a periphery of the semiconductor chip.

18. A semiconductor package comprising:
a lower package; and
an upper package stacked on the lower package,
wherein the lower package comprises:
a package body including a fan-in region and a fan-out region at least partially surrounding the fan-in region, wherein a substrate wiring structure is arranged in the package body and in the fan-out region;
a lower semiconductor chip arranged in the fan-in region;
an encapsulation layer configured to seal the semiconductor chip and the package body;
an upper redistribution structure arranged on the encapsulation layer, wherein the upper redistribution structure includes an upper redistribution metal layer and an upper redistribution insulating layer disposed on the upper redistribution metal layer, and the upper redistribution metal layer includes an upper redistribution pad formed at an upper portion thereof;
a laser mark metal layer spaced apart from the upper redistribution pad and arranged on the upper redistribution insulating layer;
an upper pad insulating layer configured to cover the upper redistribution structure and the laser mark metal layer, wherein the upper pad insulating layer includes a transparent insulating layer or a translucent insulating layer, and includes a laser mark exposure hole exposing the laser mark metal layer;
a laser mark arranged inside or on a surface of the laser mark metal layer that is exposed by the laser mark exposure hole;
a lower redistribution structure arranged under lower surfaces of the package body and the semiconductor chip and including a lower redistribution metal layer formed in the fan-in region and the fan-out region;
a lower redistribution pad arranged on the lower redistribution structure and electrically connected to the lower redistribution metal layer;
a ball land layer arranged on the lower redistribution pad;
a lower pad insulating layer disposed on the lower redistribution pad and the ball land layer; and
a lower solder ball disposed on the ball land layer,
wherein the upper package comprises:
an upper solder ball arranged on the upper redistribution pad; and
an upper semiconductor chip mounted on the upper redistribution structure and electrically connected to the upper redistribution structure via the upper solder ball.

19. The semiconductor package of claim 18, wherein the upper pad insulating layer further comprises a pad exposure hole exposing the upper redistribution pad, wherein a pad metal layer is arranged on the upper redistribution pad, and the upper redistribution pad is arranged at a same level as the laser mark metal layer.

20. The semiconductor package of claim 18, wherein the laser mark metal layer comprises a plurality of sub-metal layers, and the laser mark are arranged inside the sub-metal layers or on surfaces of the plurality of sub-metal layers.
